(19) United States
(12) Patent Application Publication
(10) Pub. No.: US 2011/0057174 A1
(43) Pub. Date: Mar. 10, 2011

(54) SEALING MATERIAL AND DISPLAY DEVICE USING THE SAME

(75) Inventor: Kie-Hyun NAM, Yongin-City (KR)

(73) Assignee: Samsung Mobile Display Co., Ltd., Yongin-City (KR)

(21) Appl. No.: 12/859,177

(22) Filed: Aug. 18, 2010

(30) Foreign Application Priority Data
Sep. 9, 2009 (KR) 10-2009-0085013

(51) Int. Cl. H01L 51/52; C09D 101/08

(52) U.S. Cl. 257/40; 106/204.01; 106/204.2; 106/204.3; 257/E51.018

(57) ABSTRACT

Disclosed are a sealing material including an inorganic particle, an organic binder, and a fiber-phased material, and a display device including the seal material.

### CROSS-REFERENCE TO RELATED APPLICATIONS

This application claims priority to and the benefit of Korean Patent Application No. 10-2009-0085013 filed in the Korean Intellectual Property Office on Sep. 9, 2009, the entire contents of which are incorporated herein by reference.

### BACKGROUND OF THE INVENTION

1. Field of the Invention

The described technology relates generally to a sealing material and a display device including the sealing material.

2. Description of the Related Art

An organic light emitting diode (OLED) device, one type of flat panel devices, includes a base substrate including an organic light emitting element thereon and an encapsulation substrate for preventing degradation of the organic light emitting element.

The base substrate and the encapsulation substrate can be attached and fixed together by a sealing material.

The sealing material can be coated on either of the base substrate or encapsulation substrate. Then, they may be attached together and hardened by heat or light.

However, in some cases there may be a defect in the form of a small void that can form as some components of the sealing material are removed during the hardening process. This defect may bring about a crack in the surface of the sealing material, which may cause a display device to be easily destroyed by an external impact.

### SUMMARY OF THE INVENTION

One embodiment provides a sealing material decreasing the incidence of defective products due to a cracks and providing a display device with a sound structure.

Another embodiment provides a display device using the sealing material.

Yet another embodiment provides a sealing material including an inorganic particle, an organic binder, and a fiber-phased material.

According to an embodiment, provided is a display device including first and second substrates facing each other, an active layer disposed therebetween, and a sealing member bonding and fixing the first and second substrates together and including a fiber-phased material.

In some embodiments the fiber-phased material has at least about a ratio of 1:5 between diameter and length.

In some embodiments, the fiber-phased material may be included in an amount of about of from about 0.1 to about 50 wt % based on the entire amount of the sealing material.

The inorganic particle and the organic binder may be included in an amount of from about 10 to about 90 wt % and from about 1 to about 20 wt % based on the entire amount of the sealing material, respectively.

The fiber-phased material may include glass fiber, carbon fiber, cellulose, or a combination thereof.

The inorganic particle may include a laser absorption material.

The inorganic particle may include SiO₂, BaO, Bi₂O₃, Al₂O₃, TiO₂, Ta₂O₅, ZnO, or a combination thereof.

The active layer may include an organic emission layer.

### BRIEF DESCRIPTION OF THE DRAWINGS

FIG. 1 is a top plan view of an organic light emitting diode (OLED) device according to one embodiment.

FIG. 2 is a cross-sectional view of organic light emitting diode (OLED) device of FIG. 1 taken along the II-II line.

### DETAILED DESCRIPTION OF THE INVENTION

This disclosure will be described more fully hereinafter with reference to the accompanying drawings, in which exemplary embodiments are shown. This disclosure may, however, be embodied in many different forms and is not to be construed as limited to the exemplary embodiments set forth herein.

In the drawings, the thickness of layers, films, panels, regions, etc., are not necessarily drawn to scale. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

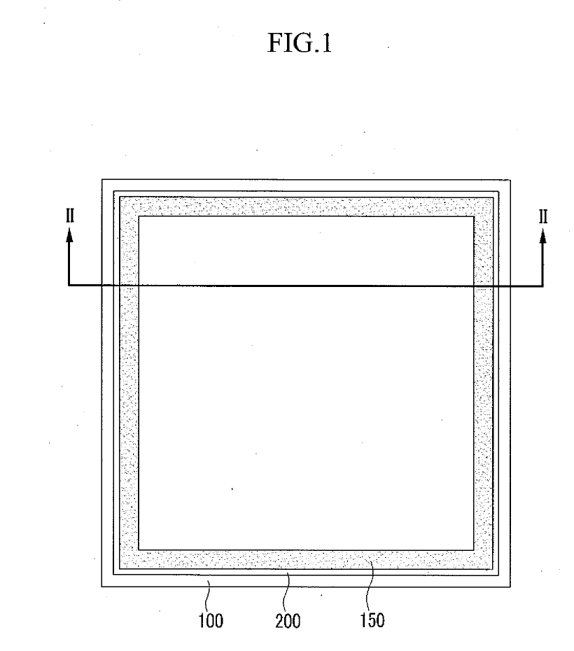

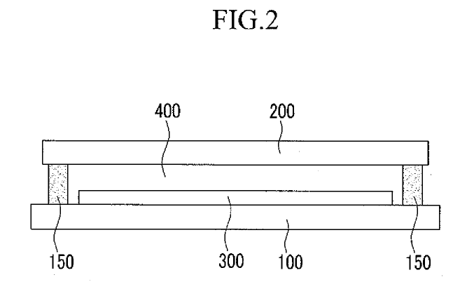

Hereinafter, illustrated is an organic light emitting diode (OLED) device according to one embodiment referring to FIGS. 1 and 2.

FIG. 1 is a top plan view of an organic light emitting diode (OLED) device according to one embodiment, and FIG. 2 is a cross-sectional view of an organic light emitting diode (OLED) device of FIG. 1 taken along the II-II line.

An organic light emitting diode (OLED) device according to one embodiment includes an organic light emitting element 300; a base substrate 100 supporting the organic light emitting element 300; an encapsulation substrate 200 sealing the organic light emitting element 300; a filler 400 filled between the base substrate 100 and the encapsulation substrate 200; and a sealing member 150 bonding and fixing the base and encapsulation substrates 100 and 200 together.

The organic light emitting element 300 includes a pair of electrodes (not shown) and an organic emission layer (not shown) disposed between the pair of electrodes.

One of the pair of electrodes is an anode, and the other is a cathode. The anode may be made of a transparent conductive material having high work function and transmitting light from the organic emission layer, for example, ITO or IZO, and the like and a hole is injected therefrom. The cathode may be made of a conductive material having low work function and little or no influence on an organic material, for example, aluminum (Al), calcium (Ca), and barium (Ba), and the like and electrons are injected therefrom.

The organic emission layer includes an organic material emitting light when a voltage is applied to a pair of electrodes.

At least one auxiliary layer (not shown) may be included between one electrode and an organic emission layer and also, between the other electrode and the organic emission layer. The auxiliary layer may include at least one of a hole transporting layer, a hole injection layer (HIL), an electron injection layer (EIL), and an electron transporting layer to balance between electrons and holes.

The base substrate 100 is positioned under the organic light emitting element 300 and supports it. The base substrate 110 may be made of, for example, glass, silicon wafer, a polymer, and the like.

The encapsulation substrate 200 may seal the organic light emitting element 300 and cut off moisture and oxygen from the outside. The encapsulation substrate 200 may be made of, for example, glass, a thin polymer film, or metal.

The filler 400 may be an inorganic filler or an organic filler.

As shown in FIG. 1, the sealing member 150 may be formed as a band shape along the edge of the base substrate 100 and the encapsulation substrate 200, but is not limited thereto. The sealing member 150 bonds and fixes the base substrate 100 and the encapsulation substrate 200.

The sealing member 150 may be formed by hardening a sealing material with heat or light such as ultraviolet rays.

The sealing material includes an inorganic particle, an organic binder, and a fiber-phased material.

The inorganic particle may be an inorganic material being capable of absorbing laser beam and for example, includes SiO₂, BaO, Bi₂O₃, Al₂O₃, TiO₂, Ta₂O₅, ZnO, or a combination thereof. The inorganic particle may have a spherical shape with a size of from about 5 nm to about 50 μm.

The inorganic particle may be included in an amount of from about 10 to about 90 wt % based on the entire amount of a sealing material.

The organic binder plays a role of bonding each component of the sealing material and for example, includes an acryl resin, ethylvinylacetate, polyvinylalcohol, and the like.

The organic binder may be included in an amount of from about 1 to about 20 wt % based on the entire amount of a sealing material.

The fiber-phased material has a long shape having a ratio of at least about 1:5 between diameter and length and for example, includes glass fiber, carbon fiber, cellulose, or a combination thereof. In some embodiments, the fiber-phased material is such that it is not fused or lost by heat or light and maintains a fiber-phase after being hardened.

The fiber-phased material may reinforce strength of the sealing member 150 and prevents the formation of a defective product. The sealing member 150 is prepared by coating a sealing material on either of the base substrate 100 or the encapsulation substrate 200, attaching them together, and then, hardening them by heat or light.

One possible problem with this process is that a part of the organic binder may be lost, which may bring about a small void space in the lost portion. Then, the sealing member may have a defect where a crack may occur along the void space by external impact.

According to one embodiment, a fiber-phased material provides a sealing member with a strong structure and may prevent its crack. In addition, the sealing member may not be easily destroyed by an external impact but maintains a strong structure.

The fiber-phased material may be included in an amount of about of from about 0.1 to about 50 wt % based on the entire amount of a sealing member.

The inorganic particle, the organic binder, and the fiber-phase material may be mixed in a solvent. The solvent may be included in a balance amount other than the inorganic particle, the organic binder, and the fiber-phased material.

This sealing material may be coated on either or both of a base substrate 100 and an encapsulation substrate 200 and then, hardened by heat or light, forming a sealing member 150.

The following examples illustrate this disclosure in more detail. These examples, however, are not in any sense to be interpreted as limiting the scope of this disclosure.

### PREPARATION OF A COMPOSITION FOR A SEALING MATERIAL

### Example 1

60 wt % of SiO₂, 5 wt % of an ethyl cellulose binder, and 10 wt % of a glass fiber chopped into a 10 μm size were prepared and mixed with α-terpineol and butyl carbitol acetate (BCA) in a remaining amount, preparing a composition for a sealing material.

### Example 2

50 wt % of SiO₂, 5 wt % of an ethyl cellulose binder, and 30 wt % of glass fiber chopped into a 10 μm size were prepared and mixed with α-terpineol and butyl carbitol acetate (BCA), preparing a composition for a sealing material.

### COMPARATIVE EXAMPLE

A composition for a sealing material was prepared according to the same method as Example 1 except that no chopped glass fiber was included.

### Evaluation

### Specimen Preparation

The compositions for a sealing material according to Examples 1 and 2 and Comparative Example were coated to be 0.8 mm wide and 10 μm high with a dispenser on the edge of a 0.5 mm thick and 2.5 inch high glass substrate and then, heat-treated in a 420° C. oven for 20 minutes to remove a solvent and a binder. Next, the glass substrate was put together with another glass substrate with the same size and then, attached by scanning them with a solid laser on the sealing region to form a hardened sealing member.

The compositions for a sealing material according to Examples 1 and 2 and Comparative Example were used to prepare ten specimens each.

### Falling Experiment

The ten specimens were respectively dropped from 2.2 m high. Then, unbroken specimens were counted to evaluate the strength.

The result is provided in Table 1.

### Adherence Evaluation

A glass substrate was attached to an acryl substrate on both sides with a both-side adhesive tape. Its adhesion strength was evaluated in an adhesion strength tester under a room temperature/room humidity condition at a speed of 100 μm/sec. The result is provided in Table 1.

TABLE 1

| | Falling experiment | Adherence |
|---|---|---|
| | (number) | (MPa) |
| Example 1 | 6 | 3.6 |
| Example 2 | 8 | 5.9 |
| Comparative | 1 | 0.7 |
| Example | | |

As shown in Table 1, the specimens prepared by using the compositions for a sealing material according to Examples 1 and 2 had excellent adherence as well as high strength compared with the one of Comparative Example.

While this disclosure has been described in connection with what is presently considered to be practical exemplary embodiments, it is to be understood that the present embodiments are not limited to the disclosed embodiments, but, on the contrary, is intended to cover various modifications and equivalent arrangements included within the spirit and scope of the appended claims.

What is claimed is:

1. A composition for a sealing material comprising:
an inorganic particle,
an organic binder, and
a fiber-phased material

2. The composition of claim 1, wherein the fiber-phased material has a ratio of at least about 1:5 between diameter and length.

3. The composition of claim 1, wherein the fiber-phased material is included in an amount from about 0.1 to about 50 wt % based on the entire amount of the sealing composition.

4. The composition of claim 3, wherein the inorganic particle is included in amount from about 10 to about 90 wt % and wherein the and the organic binder is included in an amount from about 1 to about 20 wt % based on the entire amount of the sealing composition.

5. The composition of claim 1, wherein the fiber-phased material comprises a glass fiber, a carbon fiber, cellulose, or a combination thereof.

6. The composition of claim 1, wherein the inorganic particle comprises a laser absorption material.

7. The composition of claim 6, wherein the inorganic particle comprises SiO₂, BaO, Bi₂O₃, Al₂O₃, TiO₂, Ta₂O₅, ZnO, or a combination thereof.

8. The composition of claim 1, wherein the organic binder is ethyl cellulose binder.

9. The composition of claim 1, wherein the fiber-phased material is chopped glass fiber.

10. A display device comprising the composition of claim 1.

11. A display device comprising the composition of claim 9.

12. A display device comprising:
first and the second substrates facing each other,
an active layer between the first and second substrates therebetween, and
a sealing member comprising a fiber-phased material attaching and fixing the first and second substrates.

13. The display device of claim 12, wherein the fiber-phased material has a ratio of at least about 1:5 between diameter and length.

14. The display device of claim 12, wherein the fiber-phased material comprises glass fiber, carbon fiber, cellulose, or a combination thereof.

15. The display device of claim 12, wherein the sealing member further comprises an inorganic particle and an organic binder.

16. The display device of claim 15, wherein the inorganic particle comprise a laser absorption material.

17. The display device of claim 15, wherein the inorganic particle comprises SiO₂, BaO, Bi₂O₃, Al₂O₃, TiO₂, Ta₂O₅, ZnO, or a combination thereof.

18. The display device of claim 12, wherein the active layer comprises an organic emission layer.

19. The composition of claim 15, wherein the organic binder is ethyl cellulose binder.

20. The composition of claim 12, wherein the fiber-phased material is chopped glass fiber.
